(19) United States
(12) Patent Application Publication
(10) Pub. No.: US 2018/0270970 A1
(43) Pub. Date: Sep. 20, 2018

(54) ROTARY STRUCTURE AND ELECTRONIC DEVICE USING SAME

(71) Applicants: Fu Tai Hua Industry (Shenzhen) Co., Ltd., Shenzhen (CN); HON HAI PRECISION INDUSTRY CO., LTD., New Taipei (TW)

(72) Inventors: YU-CHUN SUN, New Taipei (TW); ZHAN-SHENG LU, Shenzhen (CN)

(73) Assignees: Fu Tai Hua Industry (Shenzhen) Co., Ltd., Shenzhen (CN); HON HAI PRECISION INDUSTRY CO., LTD., New Taipei (TW)

(21) Appl. No.: 15/696,186

(22) Filed: Sep. 6, 2017

(30) Foreign Application Priority Data
Mar. 17, 2017 (CN) 201710160106.1

(51) Int. Cl. H05K 5/02; H05K 5/00

(52) U.S. Cl. CPC H05K 5/0226; H05K 5/0017

(57) ABSTRACT

An electronic device includes a rotary structure and a display screen. The rotary structure includes a first shell and two second shells. The first shell has a buckle member. Each second shell includes an annular track. The display screen is arranged on the first shell. A number of holding grooves is defined in the annular track. The buckle member is rotationally coupled to the annular track by being latched in the holding grooves to rotationally couple the second shell to the first shell. The first shell and second shell are rotatable relative to each other along the holding grooves of the annular track. An angle of view of the display screen is adjusted by rotating the first shell relative to the second shell.

### CROSS-REFERENCE TO RELATED APPLICATIONS

This application claims priority to Chinese Patent Application No. 201710160106.1 filed on Mar. 17, 2017, the contents of which are incorporated by reference herein.

### FIELD

The subject matter herein generally relates to a rotary structure and an electronic device using the rotary structure.

### BACKGROUND

Generally, a rotary structure utilizes a hinge to achieve rotation.

### BRIEF DESCRIPTION OF THE DRAWINGS

Implementations of the present technology will now be described, by way of example only, with reference to the attached figures.

FIG. 1 is an assembled, isometric view of an electronic device utilizing a rotary structure.

FIG. 2 is an enlarged view of a second shell of the rotary structure coupled to a first shell of the rotary structure.

FIG. 3 is an exploded view of FIG. 2.

FIG. 4 is similar to FIG. 3, but shows another angle.

FIG. 5 is a cross-sectional view taken along line V-V of FIG. 2.

FIG. 6 is an enlarged view of area VI-VI of FIG. 5.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected.

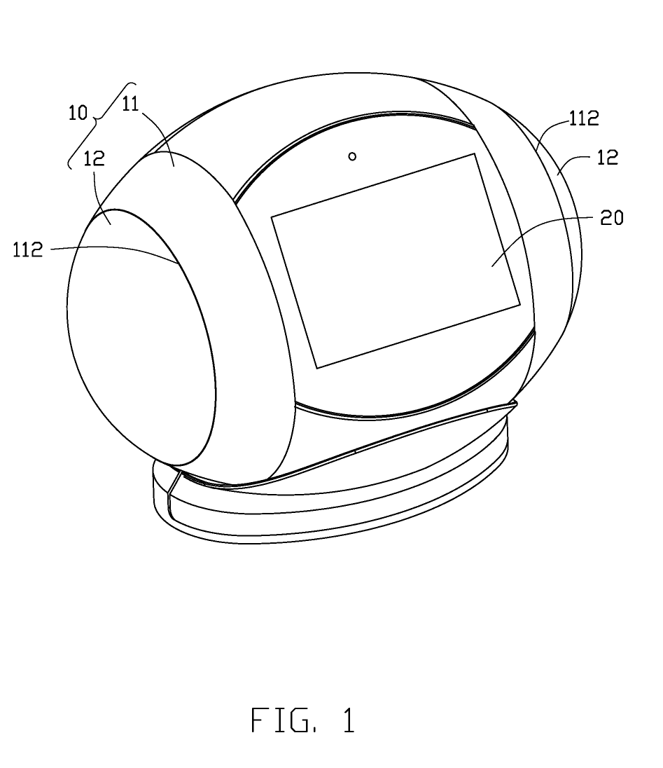

FIG. 1 illustrates an embodiment of an electronic device 1. The electronic device 1 includes a rotary structure 10 and a display screen 20. The rotary structure 10 includes a first shell 11 and at least one second shell 12. The display screen 20 is arranged on the first shell 11. In at least one embodiment, there are two second shells 12 coupled to the first shell 11. The first shell 11 includes two first end portions 112. Each first end portion 112 can rotationally couple to one corresponding second shell 12.

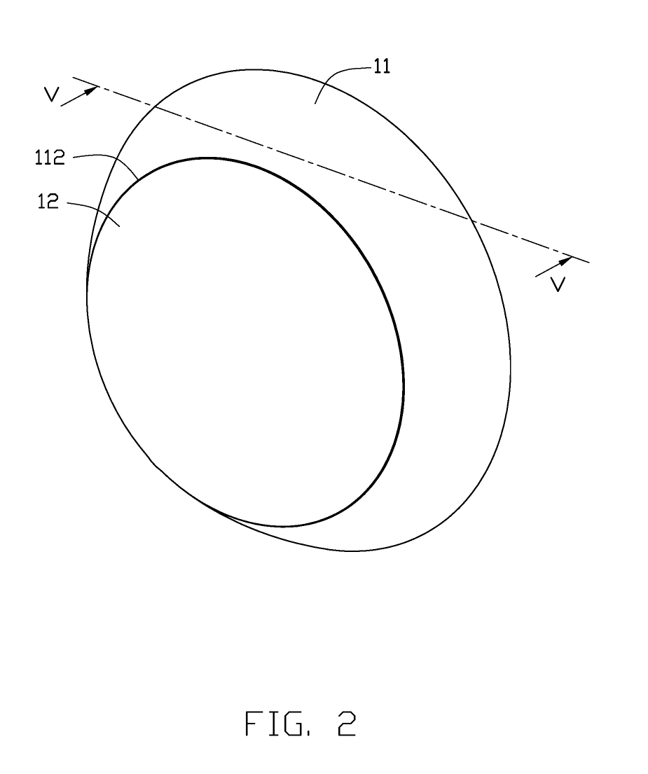

FIG. 2 illustrates the second shell 12 coupled to the first shell 11.

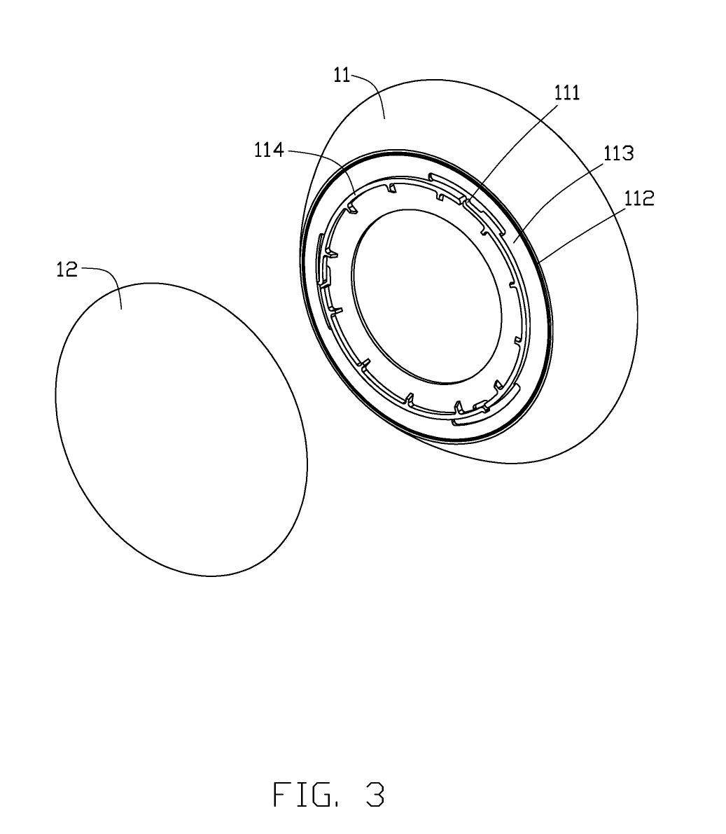

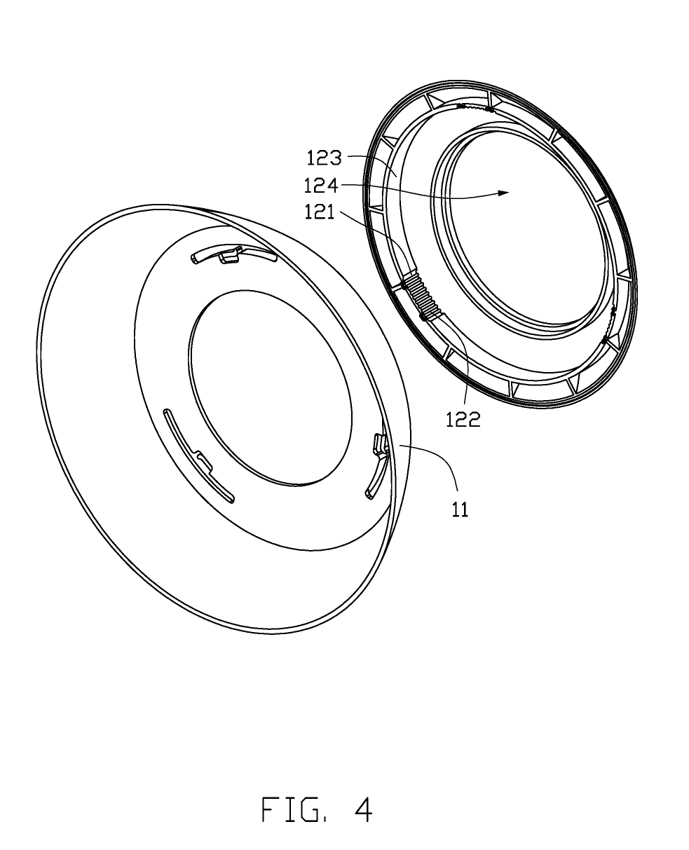

FIGS. 3-4 are exploded views of FIG. 2. The first shell 11 includes at least one buckle member 111. The second shell 12 includes at least one annular track 121 defining a plurality of holding grooves 122. The at least one buckle member 111 can be rotationally coupled to the annular track 121 by being latched in the holding grooves 122, thereby rotationally coupling the second shell 12 to the first shell 11. Thus, a viewing angle of the display screen 20 can be adjusted. In at least one embodiment, each holding groove 122 can set a different viewing angle.

Each first end portion 112 includes an end face 113 and a first annular flange 114 protruding from the end face. The buckle member 111 can be arranged on an outer surface of the first annular flange. In at least one embodiment, there are three buckle members 111, but the quantity is not limited to three. In at least one embodiment, the buckle members 111 are elongated-strip shaped.

The second shell 12 is hollow and includes a connecting end portion 125. The connecting end portion 125 is open, and a second annular flange 123 surrounds an inner wall of the connecting end portion 125. A receiving space 124 for receiving the first annular flange 114 of the first shell 11 is cooperatively defined between the second annular flange 123 and the connecting end portion 125. The annular track 121 is located on the second annular flange 123 adjacent to an inner wall of the connecting end portion 125. In at least one embodiment, there are three annular tracks 121. Each annular track 121 corresponds to one buckle member 111. The buckle members 111 can latch in the holding grooves 122 of the annular tracks 121 to set the angle of the first shell 11 relative to the second shell 12.

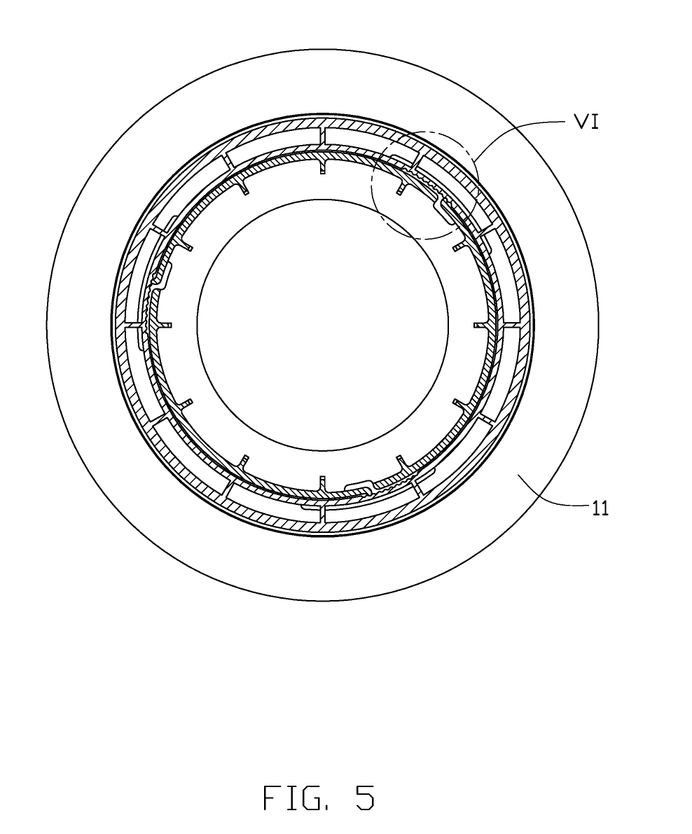

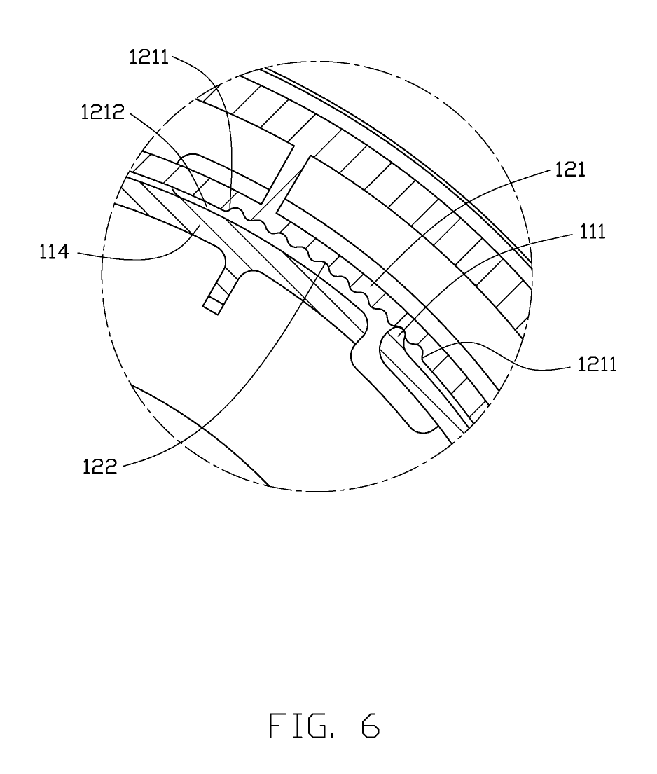

FIG. 5 is a cross-sectional view taken along line V-V of FIG. 2. FIG. 6 is an enlarged view of area VI of FIG. 5.

As shown in FIG. 6, each annular track 121 includes two opposite second end portions 1211. Each second end portion 1211 is located at one end of the annular track 121. A limiting groove 1212 is cooperatively defined between each second end portion 1211 and the first annular flange 114. The limiting grooves 1212 limit movement of the buckle member 111 to rotate along the annular track 121 between the second end portions 1211. In at least one embodiment, the limiting groove 1212 is smaller than the buckle member 111.

In another embodiment, the buckle member 111 is a protruding track (not shown) defining a plurality of second holding grooves corresponding to the plurality of holding grooves 122, and the first shell 11 can rotate relative to the second shell 12 by the plurality of second holding grooves of the buckle member 111 engaging with the annular track 121.

By using the rotary structure 10, the first shell 11 can rotate relative to the second shell 12 by the buckle member 111 and the annular track 121. Thus, the structure is simple and can ensure smooth rotation of the first shell 11 relative to the second shell 12.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

1. A rotary structure coupled to a display screen, the rotary structure comprising:
a first shell comprising a buckle member;
at least one second shell comprising an annular track;
wherein a plurality of holding grooves are defined in the annular track;
wherein the buckle member is rotationally coupled to the annular track by being latched in the plurality of holding grooves to rotationally couple the at least one second shell to the first shell; and
wherein the first shell and the at least one second shell are rotatable relative to each other along the plurality of holding grooves of the annular track to adjust an angle of the display screen relative to a horizontal plane along a rotational direction of the first shell relative to the second shell.

2. The rotary structure of claim 1, wherein the first shell comprises a first end portion, the first end portion comprises an end face and a first annular flange protruding from the end face, and the buckle member is located on an outer surface of the first annular flange.

3. The rotary structure of claim 2, wherein the at least one second shell is hollow and comprises a second annular flange surrounding an inner wall of one side of the at least one second shell, a receiving space being defined by the second annular flange, the first annular flange being received in the receiving space, and the annular track being defined on the second annular flange.

4. The rotary structure of claim 3, wherein the rotary structure comprises two second shells, one second shell located on each end of the first shell.

5. The rotary structure of claim 3, wherein the annular track comprises two second end portions, each second end portion located at one corresponding end of the annular track, a limiting groove being cooperatively defined between each second end portion and the first annular flange, the limiting grooves limiting movement of the buckle member to rotate along the annular track between the second end portions.

6. The rotary structure of claim 5, wherein each limiting groove is smaller than the buckle member.

7. The rotary structure of claim 1, wherein the buckle member is elongated-strip shaped.

8. The rotary structure of claim 1, wherein the buckle member is a protruding track, the protruding track comprising a plurality of second holding grooves corresponding to the plurality of holding grooves.

9. An electronic device comprising a rotary structure and a display screen, wherein the rotary structure comprises:
a first shell comprising a buckle member, the display screen arranged on the first shell;
at least one second shell comprising an annular track;
wherein a plurality of holding grooves are defined in the annular track;
wherein the buckle member is rotationally coupled to the annular track by being latched in the plurality of holding grooves to rotationally couple the at least one second shell to the first shell; and
wherein the first shell and at least one second shell are rotatable relative to each other along the plurality of holding grooves of the annular track to adjust an angle of the display screen relative to a horizontal plane along a rotational direction of the first shell relative to the at least one second shell.

10. The electronic device of claim 9, wherein the first shell comprises a first end portion, the first end portion comprises an end face and a first annular flange protruding from the end face, and the buckle member is located on an outer surface of the first annular flange.

11. The electronic device of claim 10, wherein the at least one second shell is hollow and comprises a second annular flange surrounding an inner wall of one side of the at least one second shell, a receiving space being defined by the second annular flange, the first annular flange being received in the receiving space, and the annular track being defined on the second annular flange.

12. The electronic device of claim 11, wherein the rotary structure comprises two second shells, one second shell located on each end of the first shell.

13. The electronic device of claim 11, wherein the annular track comprises two second end portions, each second end portion located at one corresponding end of the annular track, a limiting groove being cooperatively defined between each second end portion and the first annular flange, the limiting grooves limiting movement of the buckle member to rotate along the annular track between the second end portions.

14. The electronic device of claim 13, wherein each limiting groove is smaller than the buckle member.

15. The electronic device of claim 9, wherein the buckle member is elongated-strip shaped.

16. The electronic device of claim 9, wherein the buckle member is a protruding track, the protruding track comprising a plurality of second holding grooves corresponding to the plurality of holding grooves.
